(19) United States
(12) Patent Application Publication
(10) Pub. No.: US 2023/0137187 A1
(43) Pub. Date: May 4, 2023

(54) METHODS AND APPARATUSES FOR PREVENTION OF TEMPERATURE INTERACTION IN SEMICONDUCTOR PROCESSING SYSTEMS

(71) Applicant: ASM IP HOLDING B.V., Almere (NL)

(72) Inventor: Yukihiro Mori, Tokyo (JP)

(21) Appl. No.: 18/046,302

(22) Filed: Oct. 13, 2022

Related U.S. Application Data
(60) Provisional application No. 63/262,652, filed on Oct. 18, 2021.

(51) Int. Cl. C23C 16/46; C23C 16/52; C23C 16/458; H01L 21/67

(52) U.S. Cl. CPC C23C 16/46; C23C 16/52; C23C 16/4584; C23C 16/4586; H01L 21/67248

(57) ABSTRACT

Described herein are reactor chamber configurations in which susceptors are provided with one or more that or heaters equipped with fan-shaped separational temperature control functions. In some embodiments, the heaters, in conjunction with an active cooling mechanism may be configured to compensate for temperature non-uniformity caused by, for example, adjacent structures including heat sources and heat sinks. In some embodiments, separate temperature control may be achieved by multi-zone independent heating or cooling elements within each susceptor.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The embodiments herein are generally related to methods and apparatuses for semiconductor manufacturing.

### Description

In semiconductor and Liquid Crystal Display (LCD) manufacturing tools, susceptor heaters may be used to heat a substrate. Susceptors hold and heat semiconductor wafers during thermal processing and attempt to generate a substantially uniform temperature profile on the wafer. In typical reaction chambers, the susceptor heater surface temperature may be affected by the surrounding environment, including the reactor chamber wall and other heat sources (e.g., heat lamps or electrodes) that are operated at varying temperatures.

Conventional susceptor heaters are unable to generate a substantially uniform temperature profile on a substrate surface, especially in multi-station reaction chambers. Thus, novel methods and apparatuses for increased temperature uniformity in semiconductor processing systems are needed.

### SUMMARY

For purposes of this summary, certain aspects, advantages, and novel features of the invention are described herein. It is to be understood that not all such advantages necessarily may be achieved in accordance with any particular embodiment of the invention. Thus, for example, those skilled in the art will recognize that the invention may be embodied or carried out in a manner that achieves one advantage or group of advantages as taught herein without necessarily achieving other advantages as may be taught or suggested herein.

Some embodiments herein are directed to a semiconductor processing apparatus comprising: a process chamber comprising two or more stations; a first susceptor within a first station, the first susceptor comprising: a first independently controlled fan-shaped heating or cooling element, the first heating or cooling element configured to provide independent heating or cooling to a first heating zone of a surface of the first susceptor; and a second independently controlled fan-shaped heating or cooling element, the second heating or cooling element configured to provide independent heating or cooling to a second heating zone of a surface of the first susceptor; a second susceptor within a second station, the second susceptor comprising a heater; and a controller comprising a processor and memory that provides instructions to: heat or cool the first heating zone using the first heating or cooling element; heat or cool the second heating zone using the second heating or cooling element, wherein an amount of heat provided to or removed from the first heating zone is different from the amount of heat provided to or removed from the second heating zone, and wherein the first heating zone and the second heating zone of the surface of the first susceptor are heated or cooled to a substantially uniform first temperature; and heat the second susceptor to a second temperature using the heater, wherein the second temperature is higher than the first temperature.

In some embodiments, the first susceptor further comprises: a third independently controlled fan-shaped heating or cooling element, the third heating or cooling element configured to provide independent heating or cooling to a third heating zone of a surface of the first susceptor; and a fourth independently controlled fan-shaped heating or cooling element, the fourth heating or cooling element configured to provide independent heating or cooling to a fourth heating zone of a surface of the first susceptor.

In some embodiments, the controller provides further instructions to the apparatus to control the apparatus to: heat or cool a third heating zone of the first susceptor using the third heating or cooling element; and heat or cool a fourth heating zone of the first susceptor using the fourth heating or cooling element. In some embodiments, an amount of heat provided to or removed from the third heating zone is different from the amount of heat provided to or removed from the first heating zone, the second heating zone, and the fourth heating zone. In some embodiments, the first heating zone, the second heating zone, the third heating zone, and the fourth heating zone are heated or cooled to the substantially uniform first temperature. In some embodiments, an amount of heat provided to or removed from the fourth heating zone is different from the amount of heat provided to or removed from the first heating zone, the second heating zone, and the third heating zone. In some embodiments, the first temperature is less than 150° C. In some embodiments, the second temperature is greater than 150° C.

In some embodiments, first heating or cooling element comprises a cooling element, and wherein heating or cooling the first heating zone comprises flowing a coolant through the cooling element. In some embodiments, the first heating or cooling element comprises a heating element, wherein the heating element comprises a resistive heater, and wherein heating or cooling the first heating zone comprises providing power to the resistive heater. In some embodiments, the second heating or cooling element comprises a cooling element, and wherein heating or cooling the second heating zone comprises flowing a coolant through the cooling element.

In some embodiments, each station of the two or more stations comprises an upper chamber and a lower chamber, wherein the lower chamber comprises a shared intermediate space between the one or more stations.

Some embodiments herein are directed to a method of modulating temperature of a Quadruple-Chamber-Module (QCM) apparatus, the method comprising: providing a substrate to a process chamber comprising a first station, a second station, a third station, and a fourth station, wherein each station comprises a susceptor configured to hold the substrate, wherein the susceptor of the first station and the susceptor of the third station each comprise: a first independently controlled fan-shaped heating or cooling element, the first heating or cooling element configured to provide independent heating or cooling to a first heating zone of a surface of the susceptor; and a second independently controlled fan-shaped heating or cooling element, the second heating or cooling element configured to provide independent heating or cooling to a second heating zone of a surface of the susceptor, and wherein the susceptor of the second station and the susceptor of the fourth station each comprise a heater; heating the susceptor of the second station and the susceptor of the fourth station to a first temperature using the heater of each susceptor; controlling a temperature of the first heating zone of the first susceptor and the third susceptor using the first heating or cooling element; and controlling a temperature of the second heating zone of the first susceptor and the third susceptor using the second heating or cooling element, wherein an amount of heat provided to or removed from the first heating zone of the first susceptor and the third susceptor is different from the amount of heat provided to or removed from the second heating zone of the first susceptor and the third susceptor, and wherein the temperature of the first heating zone and the temperature of the second heating zone of the surface of the first susceptor and the third susceptor are controlled to provide a substantially uniform second temperature on the surface.

In some embodiments, the second temperature is less than 150° C. In some embodiments, the first temperature is greater than 150° C. In some embodiments, the first heating or cooling element comprises a cooling element, and wherein controlling a temperature of the first heating zone comprises flowing a coolant through the cooling element.

In some embodiments, the method further comprises detecting the first temperature, wherein controlling a temperature of the first heating zone further comprises reducing the temperature of the first heating zone relative to the detected first temperature.

In some embodiments, the first heating or cooling element comprises a heating element, wherein the heating element comprises a resistive heater, and wherein controlling a temperature of the first heating zone comprises providing power to the resistive heater.

In some embodiments, each station comprises an upper chamber and a lower chamber, wherein the lower chamber comprises a shared intermediate space between the four stations.

Some embodiments herein are directed to a method for flowable gap-fill deposition, the method comprising: (a) placing a substrate on a first susceptor in a first station, the first susceptor comprising: a first independently controlled fan-shaped heating or cooling element, the first heating or cooling element configured to provide independent heating or cooling to a first heating zone of a surface of the first susceptor; and a second independently controlled fan-shaped heating or cooling element, the second heating or cooling element configured to provide independent heating or cooling to a second heating zone of a surface of the first susceptor; (b) depositing a flowable material on the substrate in the first station by a vapor deposition process, wherein during the deposition process, the first susceptor is heated or cooled to a substantially uniform first temperature by: heating or cooling the first heating zone using the first heating or cooling element; and heating or cooling the second heating zone using the second heating or cooling element, wherein an amount of heat provided to or removed from the first heating zone is different from the amount of heat provided to or removed from the second heating zone, and wherein the first heating zone and the second heating zone are heated or cooled to the substantially uniform first temperature; (c) after depositing the flowable material on the substrate, placing the substrate in the second station; (d) performing a thermal treatment on the substrate by heating a surface of the substrate to a second temperature in the second station, wherein the second temperature is higher than the substantially uniform first temperature; and repeating (a)-(d) in a cycle until a film of desired thickness is deposited on the substrate.

In some embodiments, the substantially uniform first temperature is less than about 150° C. In some embodiments, the second temperature is between about 300° C. and about 1000° C. In some embodiments, the thermal treatment comprises a rapid thermal anneal (RTA). In some embodiments, the RTA comprises heating a surface of the substrate to the second temperature for less than 10 seconds. In some embodiments, the second temperature is between 800° C. and 1000° C.

In some embodiments, the film comprises a SiNH or SiCNH film. In some embodiments, the film fills at least 90% of a gap on the surface of the substrate. In some embodiments, the substrate comprises silicon or germanium.

### BRIEF DESCRIPTION OF THE DRAWINGS

The drawings are provided to illustrate example embodiments and are not intended to limit the scope of the disclosure. A better understanding of the systems and methods described herein will be appreciated upon reference to the following description in conjunction with the accompanying drawings, wherein:

FIG. 1A illustrates an example conventional dual-station apparatus.

FIG. 1B illustrates an example of non-uniformity of susceptor heater temperatures in a conventional dual-station apparatus.

FIG. 2A illustrates an example conventional QCM apparatus.

FIG. 2B illustrates an example of non-uniformity of susceptor heater temperatures in a conventional QCM apparatus.

FIG. 3A illustrates a top view of an example conventional susceptor having a concentric multi-zone heater.

FIG. 3B illustrates a cross-sectional view of an example conventional susceptor having a concentric multi-zone heater.

FIGS. 4A-4C illustrate example multi-zone heating/cooling elements with independent temperature control functions according to some embodiments herein.

FIG. 5 illustrates an example of a reactor chamber configuration according to some embodiments herein.

FIGS. 6A-6C illustrate example susceptor surface temperature profiles achievable using the susceptor heating/cooling configurations described herein.

FIG. 7 illustrates a substrate rotational unit to implement an in-situ multi-station process according to some embodiments herein.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

Certain exemplary embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present technology.

The embodiments here relate to methods and apparatuses for providing increased temperature uniformity for substrates in semiconductor processing systems. Temperature interaction, which refers to the interaction between two or more heat sources or heat sinks within semiconductor processing systems, may create undesirable non-uniform temperature profiles on the surface of substrates during processing. Thus, the methods and apparatuses herein may improve temperature uniformity by compensating for thermal interaction by high temperature or low temperature elements within or adjacent to a reaction chamber. Such methods and apparatuses may be particularly applicable to multi-station process chambers, including Multi-Process Quadruple-Chamber-Module (QCM) apparatuses, such as those described in U.S. Patent Application No. 63/094,768, entitled “METHODS AND APARATUSES FOR FLOWABLE GAP-FILL”, filed Oct. 21, 2020, which is hereby incorporated by reference in its entirety.

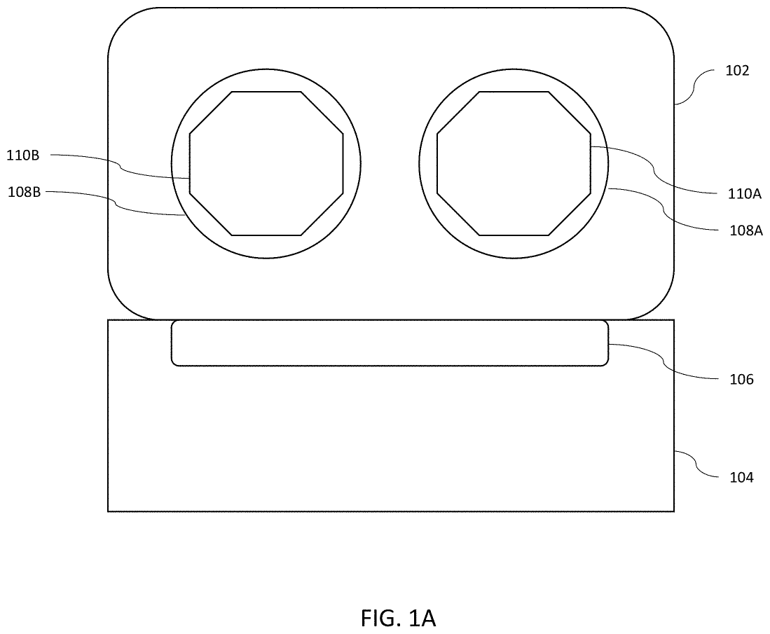

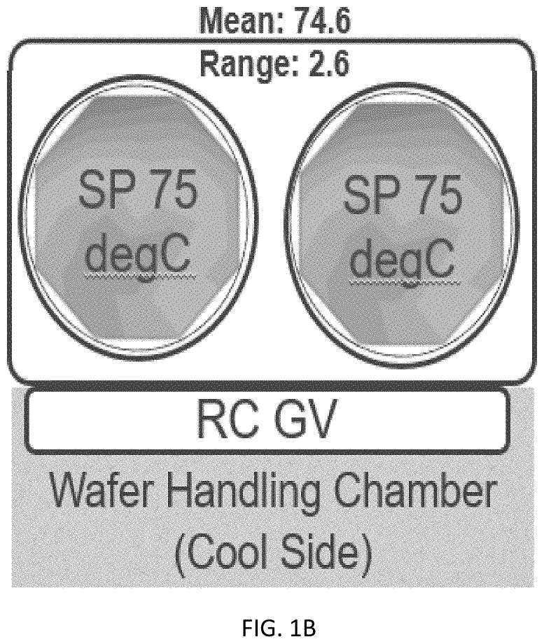

FIG. 1A illustrates an example conventional dual-station reaction chamber. A conventional dual station reaction chamber may comprise a processing chamber 102, separated from a wafer handling chamber 104 by chamber walls and a gate valve 106. The processing chamber may comprise two susceptors 108A, 108B, each susceptor comprising a heater and configured to hold a substrate 110A, 110B. Using a conventional susceptor heating configuration, a temperature non-uniformity will be formed on the surface of the substrate due differences in temperature between the susceptors 110A, 110B and the surrounding chamber walls. In particular, the temperature of the chamber walls on the side of the wafer handling chamber 104 may be lower than the temperature of within the processing chamber 102 and at the surface of the heater of susceptors 108A, 108B. As the wafer handling chamber 104 is cooled down to protect the wafer transfer mechanisms therein, the susceptor heater temperature near the chamber wall adjacent to the wafer handling chamber 104 is lowered. This lowered temperature in a portion of the susceptor heater creates undesirable temperature non-uniformity. FIG. 1B illustrates an example of non-uniformity of susceptor heater temperatures in a conventional dual-station apparatus. As illustrated in FIG. 1B, the temperature of the susceptor heaters is lower near the chamber wall adjacent to wafer handling chamber 104.

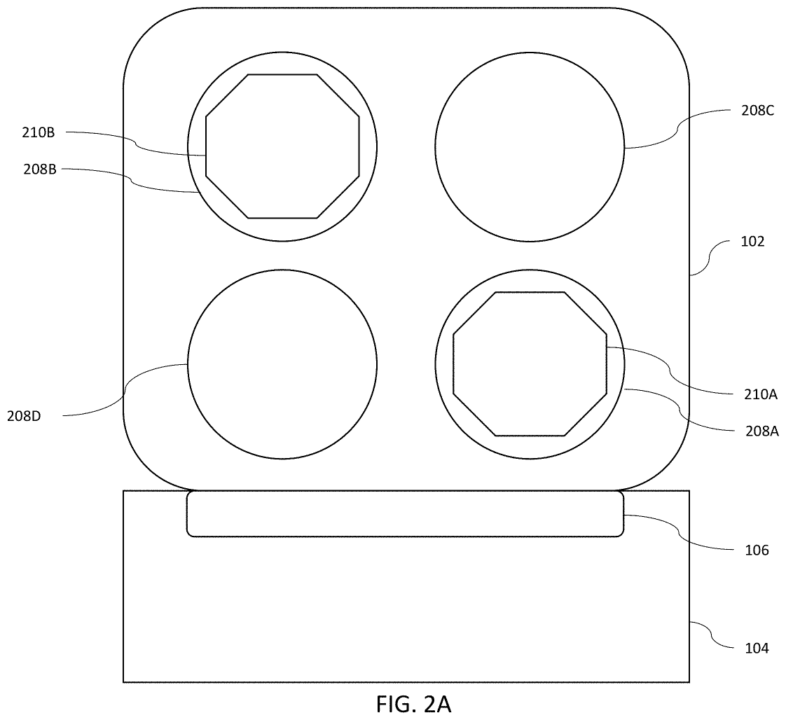

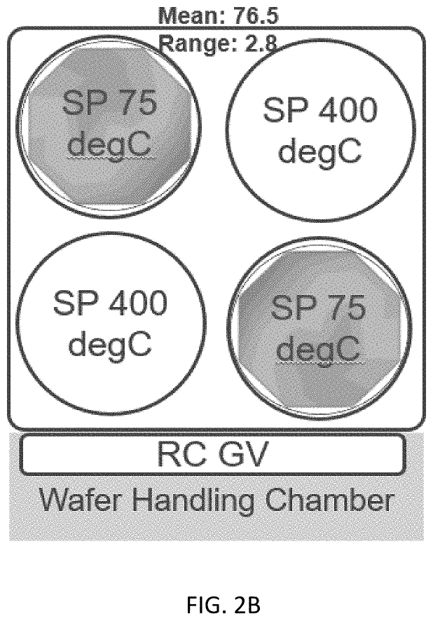

FIG. 2A illustrates an example of a conventional QCM apparatus. In a multi-process QCM apparatus, a configuration may be utilized in which each susceptor 208A, 208B, 208C, 208D has an independent heater, such that processes using different heater temperatures may be performed simultaneously on substrates 210A, 210B within processing chamber 202. In an example configuration, heaters of susceptors 208C, 208D may be operated at about 400 ° C., while heaters of susceptors 208A, 208B are operated at about 75° C. FIG. 2B illustrates an example of non-uniformity of susceptor heater temperatures in a conventional QCM apparatus in the above-noted configuration. As illustrated, the heaters of susceptors 208A, 208B show significant temperature variation due to thermal interaction with high temperature susceptor heaters 208C, 208D. This tilted type of temperature non-uniformity cannot be solved using conventional concentric multi-zone heaters.

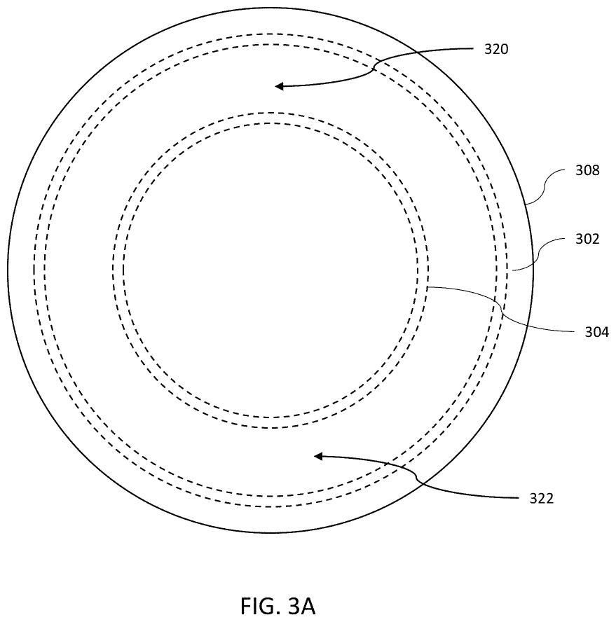

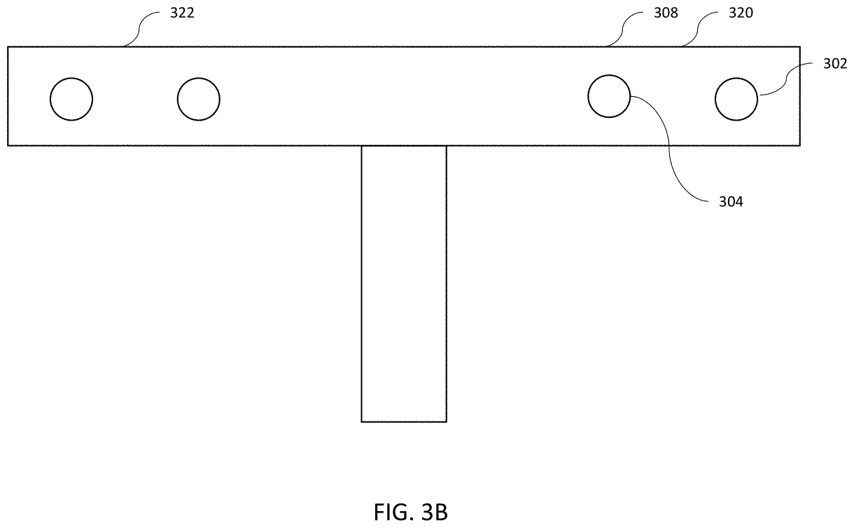

FIG. 3A illustrates a top view of an example conventional susceptor having a concentric multi-zone heater. As illustrated, susceptor 308 comprises concentric heaters including outer concentric heater 302 and inner concentric heater 304. Each of the concentric heaters are provide induction heating to the top surface of the susceptor in concentric zones of the susceptor. The heaters 302, 304 are configured to provide consistent heating to the respective heating zones but are unable to provide granular heating to specific portions of each respective zone. For example, heater 302 may not provide a different level of heating to an upper portion 320 of susceptor 302 relative to a lower portion 322 of susceptor 302. As such, the heater configuration of FIG. 3A is unable to compensate for certain temperature non-uniformities that exist on the surface of the susceptor due to temperature interactions by other structures or heat sources in or adjacent to the processing chamber.

FIG. 3B illustrates a cross-sectional view of an example conventional susceptor having a concentric multi-zone heater. As described above with respect to FIG. 3A, concentric heaters 302, 304 may be provided within or on susceptor 308. Heater 304 may be configured to provide heat to a first, inner concentric heating zone on the top surface of susceptor 308, while heater 302 may be configured to provide heat to a second, outer concentric heating zone on the top surface of susceptor 308. Thus, different levels of heat may be provided to the inner concentric heating zone and the outer concentric heating zone. However, different heating levels cannot be provided to different portions of the susceptor 308, such as upper portion 320 of susceptor 302 relative to a lower portion 322 of susceptor 302.

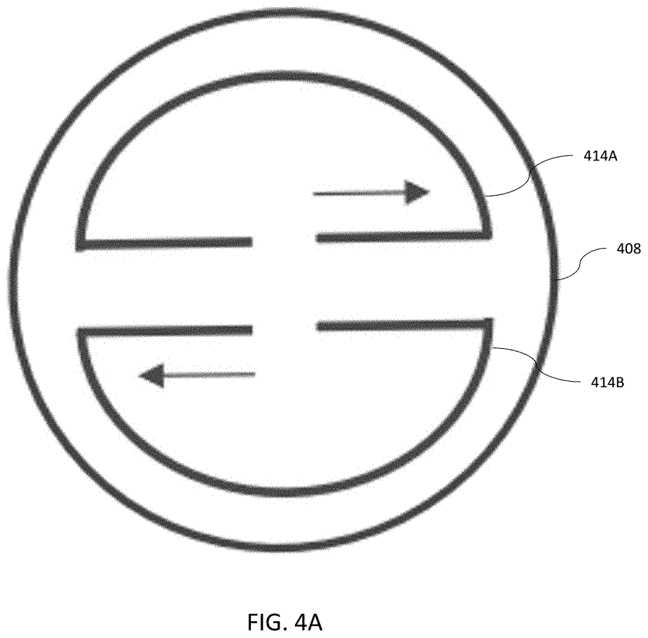

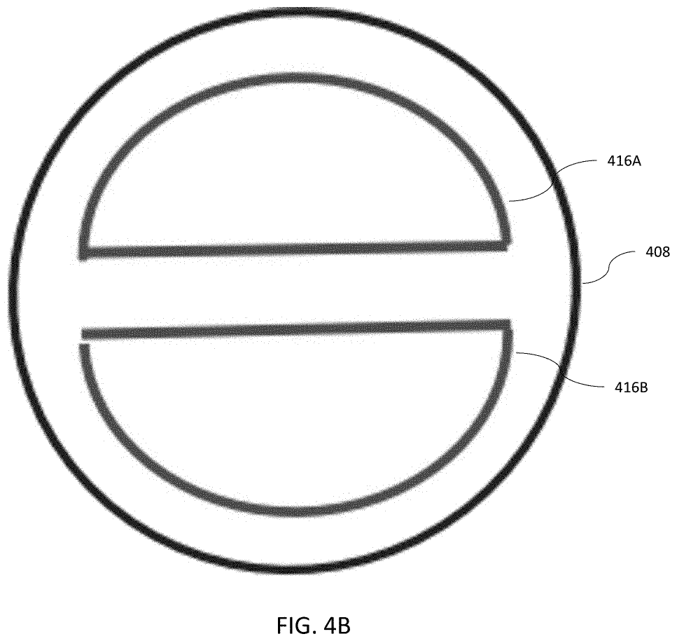

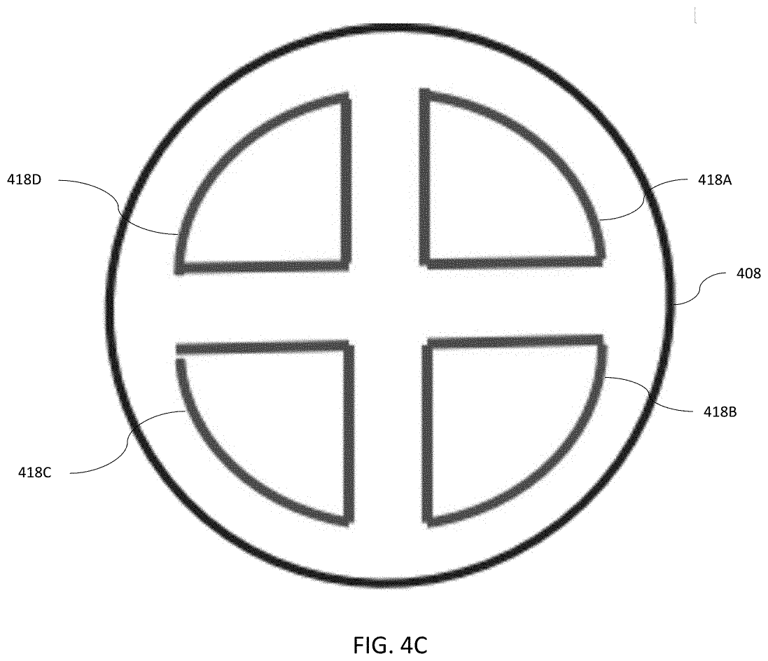

According to some embodiments herein, a susceptor heater/cooler may comprise multiple fan-shaped heating and/or cooling zones. In some embodiments, the susceptor heater/cooler may comprise one or more heating and/or cooling zones, each heating and/or cooling zone comprising a full or partial sector of a circle. For example, each heating and/or cooling zone may comprise a part of a circle made of the arc of the circle along with its two radii. In some embodiments, the radii may refer to the entire radius of the circular susceptor or to a radius of a circle that is smaller than the circular susceptor, as shown in FIGS. 4A-4C. In some embodiments, the arc may comprise two endpoints, wherein the endpoints cover a range between about 0° and 360°. For example, in some embodiments, the arc may comprise cover a range of about 0°, about 5°, about 10°, about 15°, about 20°, about 25°, about 30°, about 35°, about 40°, about 45°, about 50°, about 55°, about 60°, about 65°, about 70°, about 75°, about 80°, about 85°, about 90°, about 95°, about 100°, about 105°, about 110°, about 115°, about 120°, about 125°, about 130°, about 135°, about 140°, about 145°, about 150°, about 155°, about 160°, about 165°, about 170°, about 175°, about 180°, about 185°, about 190°, about 195°, about 200°, about 205°, about 210°, about 215°, about 220°, about 225°, about 230°, about 235°, about 240°, about 245°, about 250°, about 255°, about 260°, about 265°, about 270°, about 275°, about 280°, about 285°, about 290°, about 295°, about 300°, about 305°, about 310°, about 315°, about 320°, about 325°, about 330°, about 335°, about 340°, about 345°, about 350°, about 355°, about 360°, or any value between the aforementioned values. FIGS. 4A-4C illustrate example multi-zone heating/cooling elements with independent temperature control functions. In some embodiments, as illustrated in FIG. 4A, a susceptor 408 may comprise a dual-active cooling line comprising an upper portion cooling line 414A and a lower portion cooling line 414B. In some embodiments, as illustrated in FIG. 4B, the susceptor 408 may comprise a dual zone heater comprising an upper portion heater 416A and a lower portion heater 416B, each of which may be independently controlled to provide different levels of heat to respective first or second heating zones. In some embodiments, the heaters described herein may comprise resistive heaters, which may be heated by providing power to the resistive heater. In other embodiments, the heater may comprise other types of heaters as known to those in the art of semiconductor processing. In some embodiments, the heat provided by the upper portion heater 416A and the lower portion heater 416B may be controlled to compensate for the tilted temperature non-uniformity due to temperature interactions by other structures or heat sources in or adjacent to the processing chamber. For example, in a dual susceptor processing chamber configuration as shown in FIGS. 1A-1B, lower portion heater 416B may be controlled to provide greater heating to the lower portion of the susceptor than the heating provided to the upper portion of the susceptor by the upper portion heater 416A. These differing heating levels may compensate for temperature interaction between the susceptors and the processing chamber wall adjacent to wafer handling chamber 104.

FIG. 4C illustrates an example of a four-zone susceptor heater configuration. In some embodiments, the four-zone heater configuration of FIG. 4C may provide even more granular control of susceptor heating than the two-zone configuration of FIG. 4B. In some embodiments, susceptor 408 may comprise four fan-shaped heaters 418A, 418B, 418C, 418D, each with an associated heating zone in four quadrants of susceptor 408. In some embodiments, the heaters/heating zones may comprise a semi-circular shape, a partial circle, or a sector of a circle. In some embodiments, each heater 418A, 418B, 418C, 418D may be independently controlled to provide varying levels of heat within the respective first, second, third, or fourth heating zones. These differing heating levels may compensate for temperature interaction between the susceptors and the processing chamber wall adjacent to wafer handling chamber 104.

In some embodiments, a multi-zone susceptor heater configuration may be utilized. For example, in some embodiments, a multi-zone heater configuration may comprise 2 heaters, 3 heaters, 4 heaters, 5 heaters, 6 heaters, 7 heaters, 8 heaters, 9 heaters, 10 heaters, 11 heaters, 12 heaters, 13 heaters, 14 heaters, 15 heaters, 16 heaters, 17 heaters, 18 heaters, 19 heaters, 20 heaters, 25 heaters, 30 heaters, 35 heaters, 40 heaters, 45 heaters, 50 heaters, 55 heaters, 60 heaters, 65 heaters, 70 heaters, 75 heaters, 80 heaters, 85 heaters, 90 heaters, 95 heaters, 100 heaters, 200 heaters, 300 heaters, 400 heaters, 500 heaters, or any number of heaters between the aforementioned values.

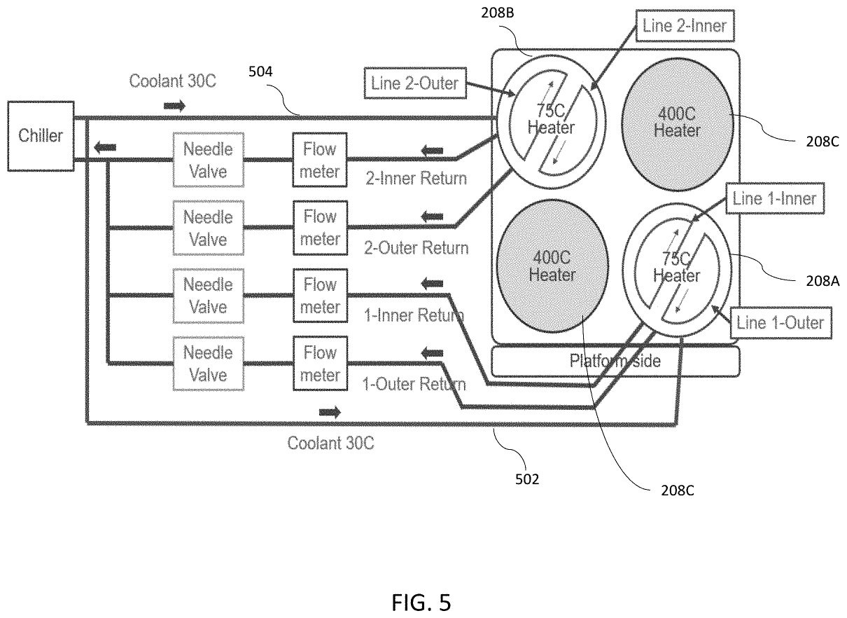

FIG. 5 illustrates an example of a reactor chamber configuration according to some embodiments herein. In some embodiments a cooling system may be implemented comprising a chiller (e.g., coolant source), which may flow coolant to active coolers within one or more susceptors. In some embodiments, coolant may be flowed to two susceptors 208A, 208B of a QCM reaction chamber via coolant lines 502, 504 respectively. The coolant may flow through an inner and outer cooling line within each of susceptors 208A, 208B, and return to the chiller through return lines. In some embodiments, each return line may be equipped with a flow meter and needle valve. In some embodiments, the flow meters, needle valves, and chiller may be in electronic communication with a controller configured to control the heating and cooling systems of the reaction chamber. In some embodiments, the controller may comprise a one or more computer processors and memory with computer-readable instructions for controlling heating and cooling of susceptors 208A, 208B, 208C, 208D. In some embodiments, one or more temperature sensors may be utilized in electronic communication with the controller.

One or more of susceptors 208A, 208B, 208C, 208D may comprise heaters in the configuration shown in FIG. 4B or 4C. The heaters may be configured with a two-way active cooling function as shown in FIG. 5. In some embodiments, susceptor heaters of one or more susceptors 208A, 208B, 208C, 208D may be controlled to heat a surface of the respective susceptor to a first temperature, while susceptor heaters of one or more susceptor 208A, 208B, 208C, 208D may be independently controlled to heat one or more other susceptor 208A, 208B, 208C, 208D to a second temperature, wherein the first temperature is different from the second temperature. For example, as shown in FIG. 5, susceptors 208A, 208B may be heated to a first temperature (e.g., about 75° C.), while susceptors 208C, 208D may be heated to a second temperature (e.g., about 400° C.). In some embodiments, the active cooling systems of susceptors 208A, 208B may be operated to bring the susceptors to the first temperature. Additionally, as described above with respect to FIGS. 4B and 4C, the heaters of susceptors 208A, 208B may be configured to provide different levels of heat to different heating zones of susceptors 208A, 208B to compensate for temperature interaction between the susceptors 208A, 208B and the processing chamber wall adjacent to a wafer handling chamber. When using a heater configuration such as those shown in FIGS. 4B and 4C, temperature uniformity can be maintained at the surface of susceptors 208A, 208B, which is desirable for substrate processing.

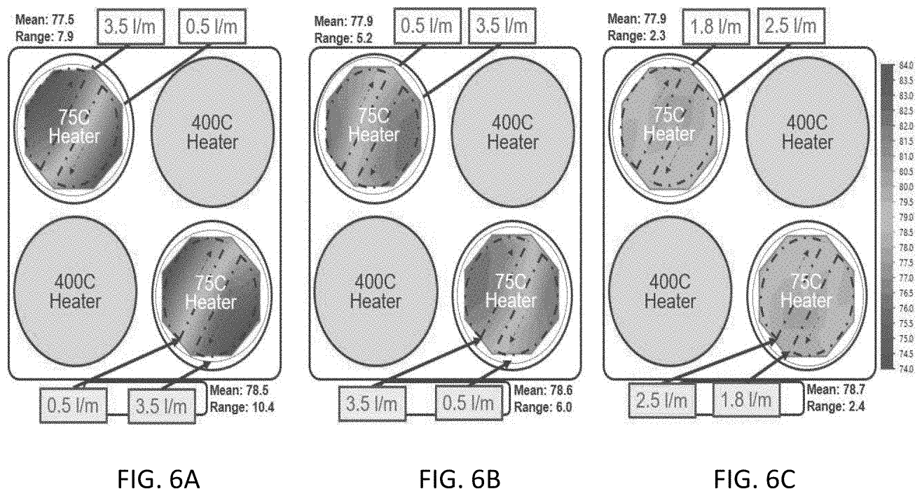

FIGS. 6A-6C illustrate example susceptor surface temperature profiles achievable using the susceptor heating/cooling configurations described herein. As shown in FIGS. 6A and 6B, susceptor temperature profiles may controlled in any way by tuning the coolant flow rate for cooling lines within susceptors 408A, 408B. In the configuration of FIG. 6A, coolant flow is controlled to produce a temperature profile similar to that in a conventional QCM reaction chamber, such as that shown in FIG. 2B. In some embodiments, coolant flow may be changed dynamically in response to temperature readings within each heating zone. However, as shown in FIG. 6B, the temperature profile (i.e., temperature tilt) can be controlled such that the reverse trend can be achieved, wherein the outer edges of susceptors 408A, 408B, closest to the chamber walls and furthest from adjacent susceptor heaters, are hotter than the inner edges. Preferably, tuning of the coolant flow rate may be optimized to provide a substantially uniform temperature profile, such as that shown in FIG. 6C.

Thus, described herein are reactor chamber configurations in which susceptors are provided with one or more that or heaters equipped with fan-shaped separational temperature control functions. In some embodiments, the heaters, in conjunction with an active cooling mechanism may be configured to compensate for temperature non-uniformity caused by, for example, adjacent structures including heat sources and heat sinks. In some embodiments, separate temperature control may be achieved by multi-zone heating or cooling elements within each susceptor.

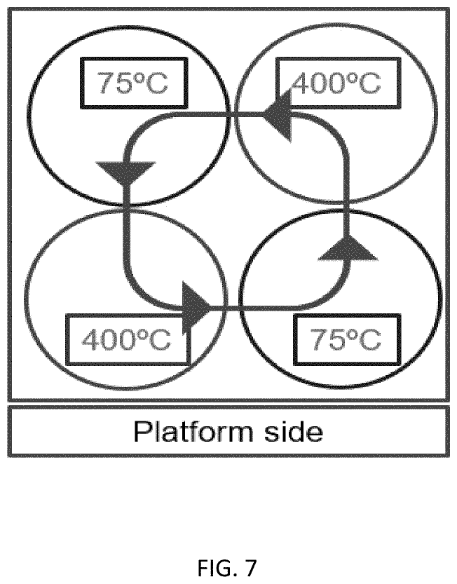

In some embodiments, the temperature control structures and functions described herein may be combined with an in-situ (i.e., in-chamber or in-module) substrate rotational unit to implement an in-situ multi-station process, wherein each station is configured to operate under different temperature, as shown in FIG. 7. In some embodiments, the temperature control configurations described herein may be utilized in a deposition process (e.g., deposition/etching, deposition/film cure) such as that described in such as those described in US Patent Application No. 63/094,768, entitled “METHODS AND APARATUSES FOR FLOWABLE GAP-FILL”, filed Oct. 21, 2020, which is hereby incorporated by reference in its entirety. When used in a flowable gap-fill deposition process, the temperature control configurations described herein enable uniform film thickness by minimizing or eliminating unfavorable temperature interactions.

For example, in some embodiments, the temperature control structures and functions described herein may be utilized in methods for flowable gap-fill deposition. In some embodiments, the methods may comprise placing a substrate on a first susceptor in a first station. In some embodiments, the first susceptor may comprise a first independently controlled fan-shaped heating or cooling element, the first heating or cooling element configured to provide independent heating or cooling to a first heating zone of a surface of the first susceptor. In some embodiments, the first susceptor may further comprise a second independently controlled fan-shaped heating or cooling element, the second heating or cooling element configured to provide independent heating or cooling to a second heating zone of a surface of the first susceptor.

In some embodiments, the methods may further comprise depositing a flowable material on the substrate in the first station by a vapor deposition process. During the vapor deposition process, the first susceptor may be heated or cooled to a substantially uniform first temperature by heating or cooling the first heating zone using the first heating or cooling element and heating or cooling the second heating zone using the second heating or cooling element. In some embodiments, an amount of heat provided to or removed from the first heating zone is different from the amount of heat provided to or removed from the second heating zone. Furthermore, in some embodiments, the first heating zone and the second heating zone are heated or cooled to the substantially uniform first temperature.

In some embodiments, the methods may further comprise, after depositing the flowable material on the substrate, placing the substrate in the second station and performing a thermal treatment on the substrate by heating a surface of the substrate to a second temperature in the second station. In some embodiments, the second temperature is higher than the substantially uniform first temperature. In some embodiments, the above steps may be repeated in a cycle until a film of desired thickness is deposited on the substrate.

In some embodiments, the substantially uniform first temperature is less than about 150° C. For example, substantially uniform first temperature may be maintained vat about 50° C., about 55° C., about 60° C., about 65° C., about 70° C., about 75° C., about 80° C., about 85° C., about 90° C., about 95° C., about 100° C., about 105° C., about 110° C., about 115° C., about 120° C., about 125° C., about 130° C., about 135° C., about 140° C., about 145° C., about 150° C., or any value between the aforementioned values.

In some embodiments, the second temperature is between about 300 ° C. and about 1000 ° C. For example, the wafer may be heated to a temperature between about 300° C., about 310° C., about 320° C., about 330° C., about 340° C., about 350° C., about 360° C., about 370° C., about 380° C., about 390° C., about 400° C., about 410° C., about 420° C., about 430° C., about 440° C., about 450° C., about 460° C., about 470° C., about 480° C., about 490° C., about 500° C., about 510° C., about 520° C., about 530° C., about 540° C., about 550° C., about 560° C., about 570° C., about 580° C., about 590° C., about 600° C., about 610° C., about 620° C., about 630° C., about 640° C., about 650° C., about 660° C., about 670° C., about 680° C., about 690° C., about 700° C., about 710° C., about 720° C., about 730° C., about 740° C., about 750° C., about 760° C., about 770° C., about 780° C., about 790° C., about 800° C., about 810° C., about 820° C., about 830° C., about 840° C., about 850° C., about 860° C., about 870° C., about 880° C., about 890° C., about 900° C., about 910° C., about 920° C., about 930° C., about 940° C., about 950° C., about 960° C., about 970° C., about 980° C., about 990° C., about 1000° C., or any value between the aforementioned vales.

In some embodiments, the thermal treatment comprises a rapid thermal anneal (RTA). In some embodiment, RTA comprises heating a surface of the substrate to the second temperature for less than 10 seconds. During an RTA, the second temperature is between 800° C. and 1000° C.

In some embodiments, the film formed using the methods described above may comprise a SiNH or SiCNH film. In some embodiments, the film formed may comprise a-CH, SiCN, SiN, SiON, SiCO, SiCOH, SiCNH, SiCH, SiNH or SiCON. In some embodiments, the film fills at least 90% of a gap on the surface of the substrate. In some embodiments, the substrate comprises silicon or germanium.

Furthermore, in some embodiments, the temperature control structures and functions described herein may be utilized in methods of modulating temperature of a Quadruple-Chamber-Module (QCM) apparatus. In some embodiments, the methods may comprise providing a substrate to a process chamber comprising a first station, a second station, a third station, and a fourth station, wherein each station comprises a susceptor configured to hold the substrate. In some embodiments, the stations may be arranged in a square configuration, with each station at a corner of the square, as shown in FIG. 2A. In some embodiments, the susceptor of the first station and the susceptor of the third station, which may be located in a diagonal orientation relative to each other, each comprise a first independently controlled fan-shaped heating or cooling element, the first heating or cooling element configured to provide independent heating or cooling to a first heating zone of a surface of the susceptor. In some embodiments, the susceptor of the first station and the susceptor of the third station may also comprise a second independently controlled fan-shaped heating or cooling element, the second heating or cooling element configured to provide independent heating or cooling to a second heating zone of a surface of the susceptor.

In some embodiments, the susceptor of the second station and the susceptor of the fourth station each comprise a heater. The methods may further comprise heating the susceptor of the second station and the susceptor of the fourth station to a first temperature using the heater of each susceptor. The temperature of the first heating zone of the first susceptor and the third susceptor may be controlled using the first heating or cooling element. The temperature of the second heating zone of the first susceptor and the third susceptor may be controlled using the second heating or cooling element. In some embodiments, an amount of heat provided to or removed from the first heating zone of the first susceptor and the third susceptor is different from the amount of heat provided to or removed from the second heating zone of the first susceptor and the third susceptor. However, in some embodiments, the temperature of the first heating zone and the temperature of the second heating zone of the surface of the first susceptor and the third susceptor are controlled to provide a substantially uniform second temperature on the surface.

In some embodiments, the second temperature is less than 150° C. In some embodiments, the first temperature is greater than 150° C. In some embodiments, the first heating or cooling element comprises a cooling element, and wherein controlling a temperature of the first heating zone comprises flowing a coolant through the cooling element.

In some embodiments, the methods may further comprise detecting the first temperature, wherein controlling a temperature of the first heating zone further comprises reducing the temperature of the first heating zone relative to the detected first temperature. In some embodiments, the first heating or cooling element comprises a heating element, wherein the heating element comprises a resistive heater, and wherein controlling a temperature of the first heating zone comprises providing power to the resistive heater. In some embodiments, each station comprises an upper chamber and a lower chamber, wherein the lower chamber comprises a shared intermediate space between the four stations.

### Additional Embodiments

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, although this invention has been disclosed in the context of certain embodiments and examples, it will be understood by those skilled in the art that the invention extends beyond the specifically disclosed embodiments to other alternative embodiments and/or uses of the invention and obvious modifications and equivalents thereof. In addition, while several variations of the embodiments of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the embodiments of the disclosed invention. Any methods disclosed herein need not be performed in the order recited. Thus, it is intended that the scope of the invention herein disclosed should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open- ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations.

Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the invention is not to be limited to the particular forms or methods disclosed, but, to the contrary, the invention is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A semiconductor processing apparatus comprising:
a process chamber comprising two or more stations;
a first susceptor within a first station, the first susceptor comprising:
a first independently controlled fan-shaped heating or cooling element, the first heating or cooling element configured to provide independent heating or cooling to a first heating zone of a surface of the first susceptor; and
a second independently controlled fan-shaped heating or cooling element, the second heating or cooling element configured to provide independent heating or cooling to a second heating zone of a surface of the first susceptor;
a second susceptor within a second station, the second susceptor comprising a heater; and
a controller comprising a processor and memory that provides instructions to:
heat or cool the first heating zone using the first heating or cooling element;
heat or cool the second heating zone using the second heating or cooling element, wherein an amount of heat provided to or removed from the first heating zone is different from the amount of heat provided to or removed from the second heating zone, and wherein the first heating zone and the second heating zone of the surface of the first susceptor are heated or cooled to a substantially uniform first temperature; and
heat the second susceptor to a second temperature using the heater, wherein the second temperature is higher than the first temperature.

2. The apparatus of claim 1, wherein the first susceptor further comprises:
a third independently controlled fan-shaped heating or cooling element, the third heating or cooling element configured to provide independent heating or cooling to a third heating zone of a surface of the first susceptor; and
a fourth independently controlled fan-shaped heating or cooling element, the fourth heating or cooling element configured to provide independent heating or cooling to a fourth heating zone of a surface of the first susceptor.

3. The apparatus of claim 2, wherein the controller provides further instructions to the apparatus to control the apparatus to:
heat or cool a third heating zone of the first susceptor using the third heating or cooling element; and
heat or cool a fourth heating zone of the first susceptor using the fourth heating or cooling element

4. The apparatus of claim 3, wherein an amount of heat provided to or removed from the third heating zone is different from the amount of heat provided to or removed from the first heating zone, the second heating zone, and the fourth heating zone.

5. The apparatus of claim 4, wherein the first heating zone, the second heating zone, the third heating zone, and the fourth heating zone are heated or cooled to the substantially uniform first temperature.

6. The apparatus of claim 3, wherein an amount of heat provided to or removed from the fourth heating zone is different from the amount of heat provided to or removed from the first heating zone, the second heating zone, and the third heating zone.

7. The apparatus of claim 1, wherein the first temperature is less than 150° C.

8. The apparatus of claim 1, wherein the second temperature is greater than 150° C.

9. The apparatus of claim 1, wherein the first heating or cooling element comprises a cooling element, and wherein heating or cooling the first heating zone comprises flowing a coolant through the cooling element.

10. The apparatus of claim 1, wherein the first heating or cooling element comprises a heating element, wherein the heating element comprises a resistive heater, and wherein heating or cooling the first heating zone comprises providing power to the resistive heater.

11. The apparatus of claim 1, wherein the second heating or cooling element comprises a cooling element, and wherein heating or cooling the second heating zone comprises flowing a coolant through the cooling element.

12. The apparatus of claim 1, wherein each station of the two or more stations comprises an upper chamber and a lower chamber, wherein the lower chamber comprises a shared intermediate space between the one or more stations.

13. A method of modulating temperature of a Quadruple-Chamber-Module (QCM) apparatus, the method comprising:
providing a substrate to a process chamber comprising a first station, a second station, a third station, and a fourth station, wherein each station comprises a susceptor configured to hold the substrate, wherein the susceptor of the first station and the susceptor of the third station each comprise:
a first independently controlled fan-shaped heating or cooling element, the first heating or cooling element configured to provide independent heating or cooling to a first heating zone of a surface of the susceptor; and
a second independently controlled fan-shaped heating or cooling element, the second heating or cooling element configured to provide independent heating or cooling to a second heating zone of a surface of the susceptor, and
wherein the susceptor of the second station and the susceptor of the fourth station each comprise a heater;
heating the susceptor of the second station and the susceptor of the fourth station to a first temperature using the heater of each susceptor;
controlling a temperature of the first heating zone of the first susceptor and the third susceptor using the first heating or cooling element; and
controlling a temperature of the second heating zone of the first susceptor and the third susceptor using the second heating or cooling element,
wherein an amount of heat provided to or removed from the first heating zone of the first susceptor and the third susceptor is different from the amount of heat provided to or removed from the second heating zone of the first susceptor and the third susceptor, and
wherein the temperature of the first heating zone and the temperature of the second heating zone of the surface of the first susceptor and the third susceptor are controlled to provide a substantially uniform second temperature on the surface.

14. The method of claim 13, wherein the second temperature is less than 150° C.

15. The method of claim 13, wherein the first temperature is greater than 150° C.

16. The method of claim 13, wherein the first heating or cooling element comprises a cooling element, and wherein controlling a temperature of the first heating zone comprises flowing a coolant through the cooling element.

17. The method of claim 16, further comprising detecting the first temperature, wherein controlling a temperature of the first heating zone further comprises reducing the temperature of the first heating zone relative to the detected first temperature.

18. The method of claim 13, wherein the first heating or cooling element comprises a heating element, wherein the heating element comprises a resistive heater, and wherein controlling a temperature of the first heating zone comprises providing power to the resistive heater.

19. The method of claim 13, wherein each station comprises an upper chamber and a lower chamber, wherein the lower chamber comprises a shared intermediate space between the four stations.

20. A method for flowable gap-fill deposition, the method comprising:
(a) placing a substrate on a first susceptor in a first station, the first susceptor comprising:
a first independently controlled fan-shaped heating or cooling element, the first heating or cooling element configured to provide independent heating or cooling to a first heating zone of a surface of the first susceptor; and
a second independently controlled fan-shaped heating or cooling element, the second heating or cooling element configured to provide independent heating or cooling to a second heating zone of a surface of the first susceptor;
(b) depositing a flowable material on the substrate in the first station by a vapor deposition process, wherein during the deposition process, the first susceptor is heated or cooled to a substantially uniform first temperature by:
heating or cooling the first heating zone using the first heating or cooling element; and
heating or cooling the second heating zone using the second heating or cooling element, wherein an amount of heat provided to or removed from the first heating zone is different from the amount of heat provided to or removed from the second heating zone, and wherein the first heating zone and the second heating zone are heated or cooled to the substantially uniform first temperature;
(c) after depositing the flowable material on the substrate, placing the substrate in the second station;
(d) performing a thermal treatment on the substrate by heating a surface of the substrate to a second temperature in the second station, wherein the second temperature is higher than the substantially uniform first temperature; and
repeating (a)-(d) in a cycle until a film of desired thickness is deposited on the substrate.

21. The method of claim 20, wherein the substantially uniform first temperature is less than about 150° C.

22. The method of claim 20, wherein the second temperature is between about 300° C. and about 1000° C.

23. The method of claim 20, wherein the thermal treatment comprises a rapid thermal anneal (RTA).

24. The method of claim 23, wherein the RTA comprises heating a surface of the substrate to the second temperature for less than 10 seconds.

25. The method of claim 24, wherein the second temperature is between 800° C. and 1000° C.

26. The method of claim 20, wherein the film comprises a SiNH or SiCNH film.

27. The method of claim 20, wherein the film fills at least 90% of a gap on the surface of the substrate.

28. The method of claim 20, wherein the substrate comprises silicon or germanium.
